(19) United States
(12) Patent Application Publication
(10) Pub. No.: US 2025/0089288 A1
(43) Pub. Date: Mar. 13, 2025

(54) GATE CONTACT AT GATE ENDS THROUGH BACKSIDE GATE CUT

(71) Applicant: INTERNATIONAL BUSINESS MACHINES CORPORATION, ARMONK, NY (US)

(72) Inventors: Tao Li, Slingerlands, NY (US); Ruilong Xie, Niskayuna, NY (US); Julien Frougier, Albany, NY (US); Shay Reboh, Albany, NY (US)

(21) Appl. No.: 18/465,247

(22) Filed: Sep. 12, 2023

(51) Int. Cl. H01L 29/775; H01L 23/528; H01L 29/06; H01L 29/40; H01L 29/417; H01L 29/423; H01L 29/66

(52) U.S. Cl. CPC H10D 30/43; H01L 23/5286; H10D 30/014; H10D 30/6729; H10D 30/6735; H10D 62/121; H10D 64/01

(57) ABSTRACT

According to the embodiment of the present invention, a semiconductor device includes a plurality of nanodevices including a plurality of transistors. The plurality of nanodevices are located adjacent to and parallel to each other along an x-axis. A gate contact is located at an edge of a cell boundary between two nanodevices of the plurality of nanodevices. The gate contact includes a recessed portion. A backside gate cut dielectric pillar extends downwards through the recessed portion to be in direct contact with the gate contact.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device includes a plurality of nanodevices including a plurality of transistors. The plurality of nanodevices are located adjacent to and parallel to each other along an x-axis. A gate contact is located at an edge of a cell boundary between two nanodevices of the plurality of nanodevices. The gate contact includes a recessed portion. A backside gate cut dielectric pillar extends downwards through the recessed portion to be in direct contact with the gate contact.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-4 illustrate cross sections X, Y₁, and Y₂, respectively, of the plurality of nanodevices after interlayer dielectric (ILD) deposition, nanosheet formation, shallow trench isolation (STI) region formation, gate formation, gate spacer and inner spacer formation, self-aligned substrate isolation (SASI) layer formation, source/drain formation, etch stop layer formation, and CMP, in accordance with the embodiment of the present invention.

FIG. 5 illustrates a top-down view of the plurality of nanodevices after the formation of a plurality of source/drain contacts, a plurality of gate contacts, a plurality of frontside signal lines, and a plurality of vias, in accordance with the embodiment of the present invention.

FIGS. 6-8 illustrate cross sections X, Y₁, and Y₂, respectively, of the plurality of nanodevices after the formation of the plurality of source/drain contacts, the plurality of gate contacts, the plurality of frontside signal lines, and the plurality of vias, in accordance with the embodiment of the present invention.

FIGS. 9-11 illustrate cross sections X, Y₁, and Y₂, respectively, of the plurality of nanodevices after the formation of a back-end-of-line (BEOL) layer and bonding to a carrier wafer, in accordance with the embodiment of the present invention.

FIGS. 12-14 illustrate cross sections X, Y₁, and Y₂, respectively, of the plurality of nanodevices after the carrier wafer is flipped and the substrate is removed, in accordance with the embodiment of the present invention.

FIGS. 15-17 illustrate cross sections X, Y₁, and Y₂, respectively, of the plurality of nanodevices after the removal of the etch stop layer and the underlying substrate layer, in accordance with the embodiment of the present invention.

FIGS. 18-20 illustrate cross sections X, Y₁, and Y₂, respectively, of the plurality of nanodevices after backside ILD (BILD) layer deposition and CMP, in accordance with the embodiment of the present invention.

FIGS. 21-23 illustrate cross sections X, Y₁, and Y₂, respectively, of the plurality of nanodevices after the selective recessing of the STI region, in accordance with the embodiment of the present invention.

FIGS. 24-26 illustrate cross sections X, Y₁, and Y₂, respectively, of the plurality of nanodevices after the formation of a plurality of dielectric spacers, in accordance with the embodiment of the present invention.

FIGS. 27-29 illustrate cross sections X, Y₁, and Y₂, respectively, of the plurality of nanodevices after the formation of a lithography mask layer, in accordance with the embodiment of the present invention.

FIG. 30 illustrates a top-down view of the plurality of nanodevices after the formation of a first trench, in accordance with the embodiment of the present invention.

FIGS. 31-33 illustrate cross sections X, Y₁, and Y₂, respectively, of the plurality of nanodevices after the formation of the first trench, in accordance with the embodiment of the present invention.

FIGS. 34-36 illustrate cross sections X, Y₁, and Y₂, respectively, of the plurality of nanodevices after the removal of the lithography mask layer, in accordance with the embodiment of the present invention.

FIG. 37 illustrates a top-down view of the plurality of nanodevices after the formation of a plurality of dielectric fills, a backside gate cut dielectric pillar, and CMP, in accordance with the embodiment of the present invention.

FIGS. 38-40 illustrate cross sections X, Y₁, and Y₂, respectively, of the plurality of nanodevices after the formation of the plurality of dielectric fills, the backside gate cut dielectric pillar, and CMP, in accordance with the embodiment of the present invention.

FIGS. 41-43 illustrate cross sections X, Y₁, and Y₂, respectively, of the plurality of nanodevices after the formation of a second lithography mask layer, in accordance with the embodiment of the present invention.

FIGS. 44-46 illustrate cross sections X, Y₁, and Y₂, respectively, of the plurality of nanodevices after the formation of a second trench, a third trench, and a fourth trench, in accordance with the embodiment of the present invention.

FIGS. 47-49 illustrate cross sections X, Y₁, and Y₂, respectively, of the plurality of nanodevices after the formation of a plurality of backside contacts, in accordance with the embodiment of the present invention.

FIGS. 50-52 illustrate cross sections X, Y₁, and Y₂, respectively, of the plurality of nanodevices after the formation of a BSPDN, in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

When a gate contact is located over a shallow trench isolation (STI) region, the gate contact may be located between two nanodevices, for example, two nanosheet transistors. Positioning the gate contact over the STI region limits the number of signal lines available to the gate contact, resulting in a larger pitch due to the signal lines that are leveraged being wider.

By forming the gate contact at an edge of a cell boundary between two nanodevices, smaller signal lines may take the place of power rails originally located at a back-end-of-line (BEOL) cell boundary that are moved to a wafer backside as backside power rails (BPRs), which may free up space and enable more signal lines at the cell boundary. Additionally, by forming a backside gate cut as opposed to a frontside gate cut, the gate contact at the edge of the cell boundary may more easily access a gate. The present invention does not require that all advantages need to be incorporated into every embodiment of the invention.

The present invention is directed to forming a gate contact at an edge of a cell boundary between two nanodevices such that signal lines take the place of BEOL power rails at the cell boundary. The gate contact is formed through a multistage processing, where the first stage forms a gate. The second stage forms an interlayer dielectric (ILD) above the gate. The third stage forms a gate contact by depositing a conductive metal above the gate within the ILD. The fourth stage forms a via and signal line by depositing a conductive metal above the gate contact. The fifth stage forms a first trench by etching a portion of the STI region, the gate, the ILD, and the gate contact. The sixth stage fills the first trench with a dielectric material to form a backside gate cut dielectric pillar through the gate.

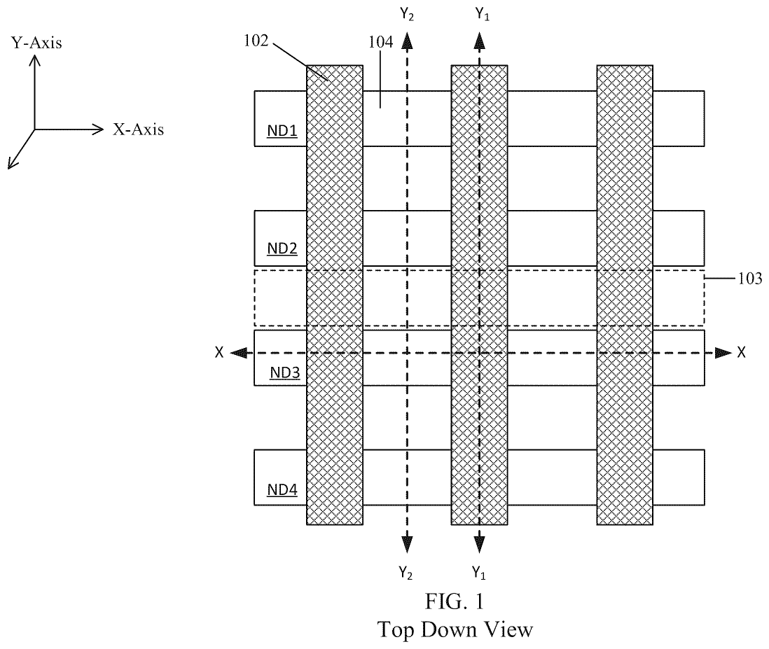

FIG. 1 illustrates a top-down view of a plurality of nanodevices ND1, ND2, ND3, ND4, in accordance with the embodiment of the present invention. The adjacent and parallel devices along an x-axis include a first nanodevice ND1, a second nanodevice ND2, a third nanodevice ND3, and a fourth nanodevice ND4 including a plurality of transistors. Cross-section X is a cross section perpendicular to the gates along the horizontal axis of the third nanodevice ND3. Cross-section Y₁ is a cross section parallel to the gates in the gate region 102 across the plurality of nanodevices ND1, ND2, ND3, ND4. Cross-section Y₂ is a cross section parallel to the gates in the source/drain region 104 across the plurality of nanodevices ND1, ND2, ND3, ND4. Dashed box 103 illustrates the cell boundary region between the second nanodevice ND2 and the third nanodevice ND3. It may be appreciated that the embodiment of the present invention is not limited to nanodevices ND1, ND2, ND3, ND4 and that other devices including, but not limited to, nanosheet transistors, FinFET, nanowire, and a planar device may also be used.

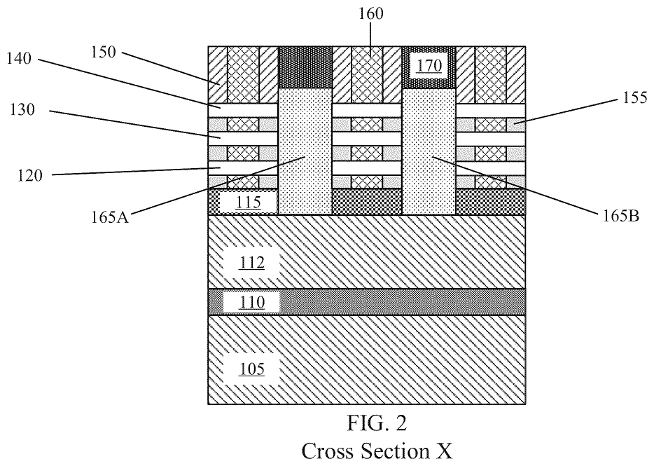

FIGS. 2-4 illustrate cross sections X, Y₁, and Y₂, respectively, of the plurality of nanodevices ND1, ND2, ND3, ND4 after interlayer dielectric (ILD) 170 deposition, nanosheet 120, 130, 140 formation, shallow trench isolation (STI) region 114 formation, gate 160 formation, gate spacer 150 and inner spacer 155 formation, self-aligned substrate isolation (SASI) layer 115 formation, source/drain 165A, 165B, 165C, 165D, 165E formation, etch stop layer 110 formation, and CMP, in accordance with the embodiment of the present invention. The plurality of nanodevices ND1, ND2, ND3, ND4 include a substrate 105, an etch stop layer 110, an underlying substrate layer 112, an STI region 114, a first nanosheet 120, a second nanosheet 130, and a third nanosheet 140. The substrate 105 and the etch stop layer 110 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 and the etch stop layer 110 may be doped, undoped or contain doped regions and undoped regions therein.

The first sacrificial layer (not shown) is formed directly atop the underlying substrate layer 112. The first nanosheet 120 is formed directly atop the first sacrificial layer (not shown). The second sacrificial layer (not shown) is formed directly atop the first nanosheet 120. The second nanosheet 130 is formed directly atop the second sacrificial layer (not shown). The third sacrificial layer (not shown) is formed directly atop the second nanosheet 130. The third nanosheet 140 is formed directly atop the third sacrificial layer (not shown). The first sacrificial layer (not shown), the second sacrificial layer (not shown), and the third sacrificial layer (not shown) are hereinafter referred to as the plurality of sacrificial layers (not shown). In addition, the first nanosheet 120, the second nanosheet 130, and the third nanosheet 140 are hereinafter referred to as the plurality of nanosheets 120, 130, 140. The plurality of sacrificial layers (not shown) may be comprised of, for example, SiGe, where Ge is about 35%. The plurality of nanosheets 120, 130, 140 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of nanosheets 120, 130, 140 and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 114 is formed by dielectric filling, CMP, and dielectric recess.

A dummy gate material is deposited and then patterned to form dummy gates (not shown), followed by gate spacer 150 and SASI layer 115 formation by a conformal dielectric liner deposition followed by anisotropic etch. The SASI layer 115 is located directly atop the underlying substrate layer 112. Then, the nanosheet stack at the S/D region 104 is recessed, followed by indentation of sacrificial layers (not shown) and inner spacer 155 formation. Then, the first source/drain 165A, the second source/drain 165B, the third source/drain 165C, the fourth source/drain 165D, and the fifth source/drain 165E are epitaxially grown over exposed sidewalls of the plurality of nanosheets 120, 130, 140, followed by ILD 170 deposition and CMP to remove a dummy gate hard mask (not shown). Then, the sacrificial layers (not shown) are removed, followed by gate 160 formation. The first source/drain 165A, the second source/drain 165B, the third source/drain 165C, the fourth source/drain 165D, and the fifth source drain 165E are formed directly atop the underlying substrate layer 112.

The first source/drain 165A, the second source/drain 165B, the third source/drain 165C, the fourth source/drain 165D, and the fifth source/drain 165E can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

In FIG. 2, the ILD 170 is formed directly atop the first source/drain 165A and the second source/drain 165B, and surrounds one side of the gate spacer 150. In FIG. 4, the ILD 170 is formed directly atop the first source/drain 165A, the third source/drain 165C, the fourth source/drain 165D, the fifth source/drain 165E, and the STI region 114.

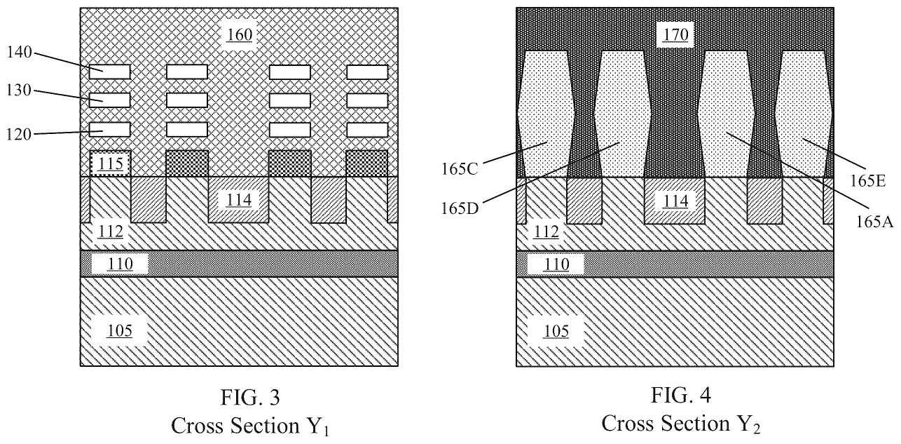

In FIG. 2, a gate material is deposited in the space created by the removal of the plurality of sacrificial layers (not shown) and directly atop the third nanosheet 140 to form a replacement gate (i.e., the gate 160). In FIG. 3, the gate material is deposited in the space created by the removal of the plurality of sacrificial layers (not shown), and directly atop the third nanosheet 140 and the STI region 114 to form the gate 160. The gate 160 can be comprised of, for example, a gate dielectric liner, such as a high-k dielectric like HfO2, ZrO2, HfLaOx, etc., and work function layers, such as TIN, TiAlC, TiC, etc., and conductive metal fills, like W.

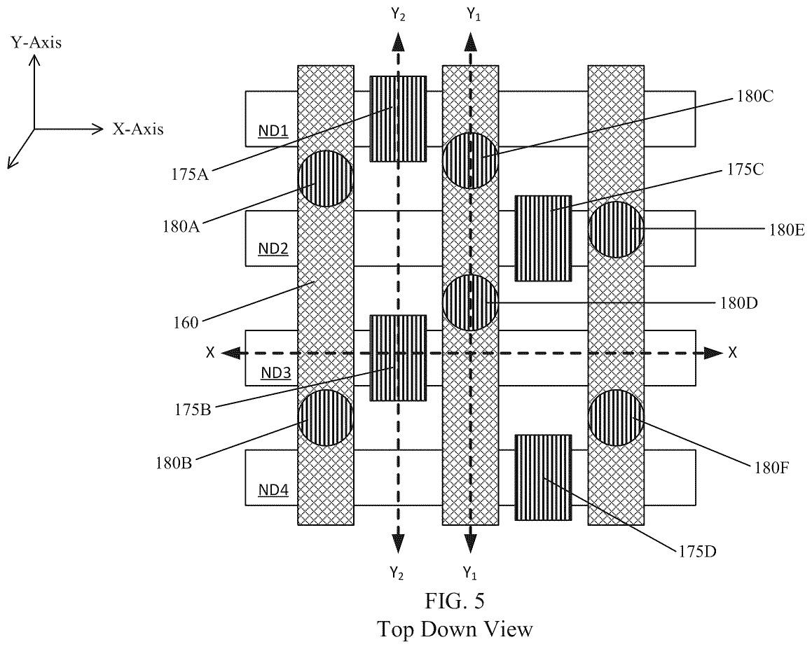

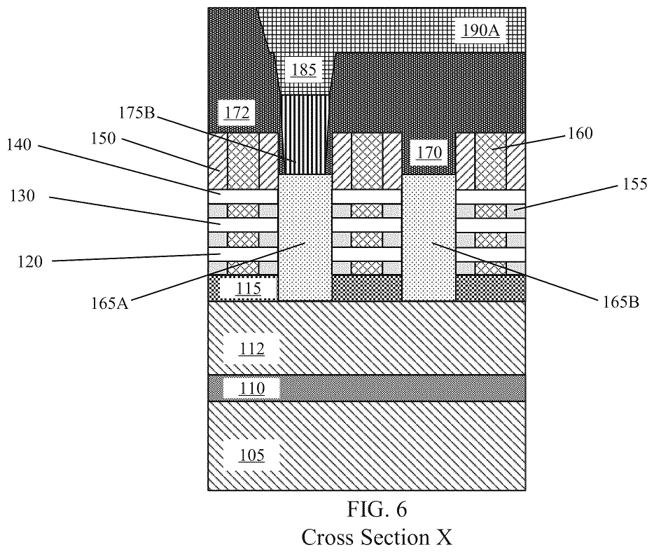

FIG. 5 illustrates a top-down view of the plurality of nanodevices ND1, ND2, ND3, ND4 after the formation of a plurality of source/drain contacts 175A, 175B, 175C, 175D, a plurality of gate contacts 180A, 180B, 180C, 180D, 180E, 180F, a plurality of frontside signal lines 190A, 190B, 190C, 190D, 190E, 190F, 190G, 190H (FIGS. 6-8), and a plurality of vias 185, 187, 188, 189 (FIGS. 6-8), in accordance with the embodiment of the present invention. FIG. 5 is meant to illustrate the location of the fourth gate contact 180D (i.e., the gate contact in the claims). The fourth gate contact 180D is located at an edge of a cell boundary between two nanodevices ND2, ND3 of the plurality of nanodevices ND1, ND2, ND3, ND4. A plurality of trenches (not shown) formed during middle-of-line (MOL) patterning are filled with a conductive metal (e.g., including a silicide liner, such as Ni, Ti, NiPt, an adhesion metal liner, such as TiN and conductive metal fill, such as W, Co, or Ru) to form the plurality of source/drain contacts 175A, 175B, 175C, 175D and the plurality of gate contacts 180A, 180B, 180C, 180D, 180E, 180F.

FIGS. 6-8 illustrate cross sections X, Y₁, and Y₂, respectively, of the plurality of nanodevices ND1, ND2, ND3, ND4 after the formation of the plurality of source/drain contacts 175A, 175B, 175C, 175D, the plurality of gate contacts 180A, 180B, 180C, 180D, 180E, 180F, the plurality of frontside signal lines 190A, 190B, 190C, 190D, 190E, 190F, 190G, 190H, and the plurality of vias 185, 187, 188, 189, in accordance with the embodiment of the present invention. The plurality of frontside signal lines 190A, 190B, 190C, 190D, 190E, 190F, 190G, 190H and the plurality of vias 185, 187, 188, 189 are patterned using conventional lithography and etching processes, followed by metallization (e.g., Cu, Co or Ru fill with adhesion liner such as TiN). In FIG. 6, an additional ILD 172 is formed directly atop the ILD 170, the gate spacer 150, and the gate 160. The second source/drain contact 175B is located directly atop the first source/drain 165A. The first frontside signal line 190A includes the first via 185. The first frontside signal line 190A including the first via 185 is located directly atop the second source/drain contact 175B. A top surface of the second source/drain contact 175B is connected to the first via 185.

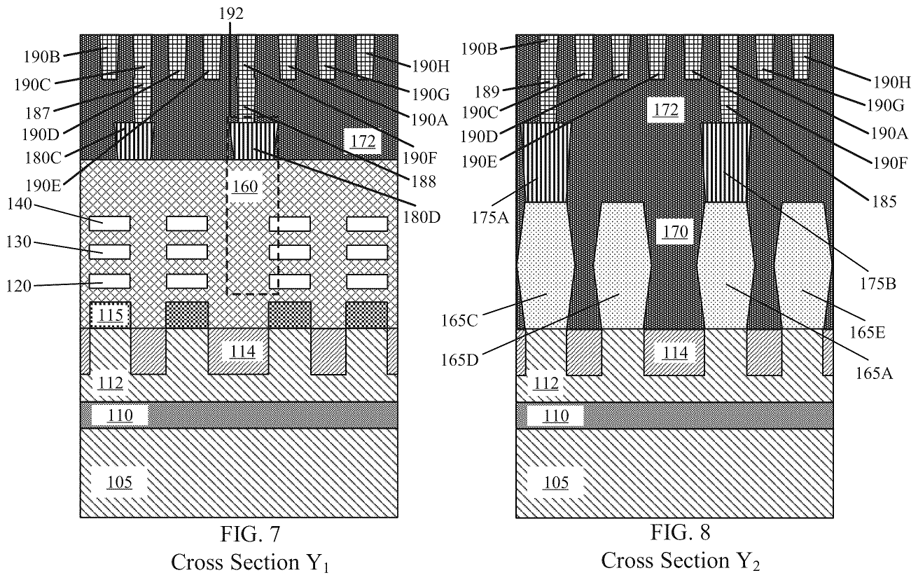

In FIG. 7, the additional ILD 172 is formed directly atop the gate 160. The third gate contact 180C and the fourth gate contact 180D are located directly atop the gate 160 and are surrounded on three sides by the additional ILD 172. The third frontside signal line 190C includes the second via 187. The third frontside signal line 190C including the second via 187 is located directly atop the third gate contact 180C. A top surface of the third gate contact 180C is connected to the second via 187. The sixth frontside signal line 190F (i.e., the frontside signal line in the claims) includes the third via 188 (i.e., the via in the claims). The sixth frontside signal line 190F including the third via 188 is located directly atop the fourth gate contact 180D. A top surface of the fourth gate contact 180D is connected to the third via 188. The second frontside signal line 190B and the fourth frontside signal line 190D are located adjacent to the third frontside signal line 190C on both sidewalls of the third frontside signal line 190C. The fifth frontside signal line 190E and the first frontside signal line 190A are located adjacent to the sixth frontside signal line 190F on both sidewalls of the sixth frontside signal line 190F. The seventh frontside signal line 190G, the eighth frontside signal line 190H, and the first frontside signal line 190A are substantially in a same plane. The fourth gate contact 180D is located between the second nanodevice ND2 and the third nanodevice ND3. Dashed box 192 illustrates the fourth gate contact 180D partially overlapping the third nanodevice ND3. Dashed box 192 also illustrates the sixth frontside signal line 190F located at the cell boundary between two nanodevices ND2, ND3 of the plurality of nanodevices ND1, ND2, ND3, ND4. The sixth frontside signal line 190F including the third via 188 connects to a frontside of the fourth gate contact 180D.

In FIG. 8, the additional ILD 172 is formed directly atop the ILD 170. The first source/drain contact 175A is located directly atop the third source/drain 165C. The second source/drain contact 175B is located directly atop the first source/drain 165A. The second frontside signal line 190B includes the fourth via 189. The second frontside signal line 190B including the fourth via 189 is located directly atop the first source/drain contact 175A. A top surface of the first source/drain contact 175A is connected to the fourth via 189. The first frontside signal line 190A includes the first via 185. The first frontside signal line 190A including the first via 185 is located directly atop the second source/drain contact 175B. The top surface of the second source/drain contact 175B is connected to the first via 185. The sixth frontside signal line 190F and the seventh frontside signal line 190G are located adjacent to the first frontside signal line 190A on both sidewalls of the first frontside signal line 190A. The third frontside signal line 190C, the fourth frontside signal line 190D, the fifth frontside signal line 190E, the eighth frontside signal line 190H, and the seventh frontside signal line 190G are substantially in the same plane.

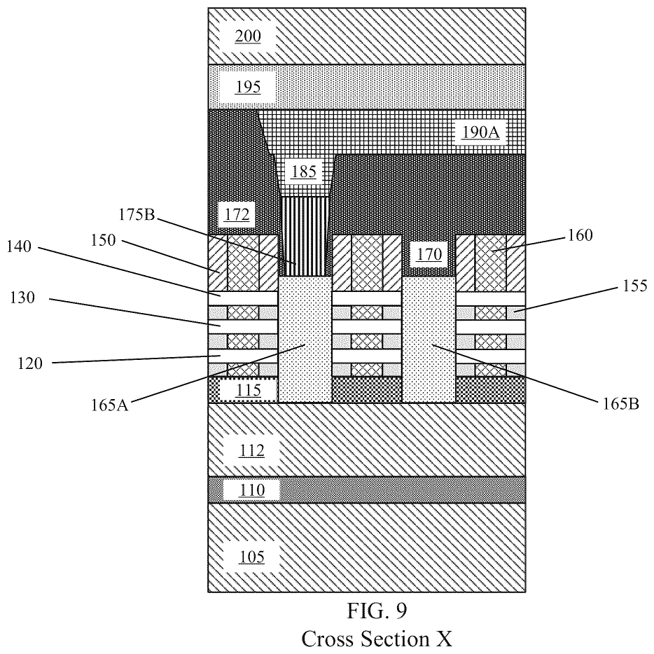

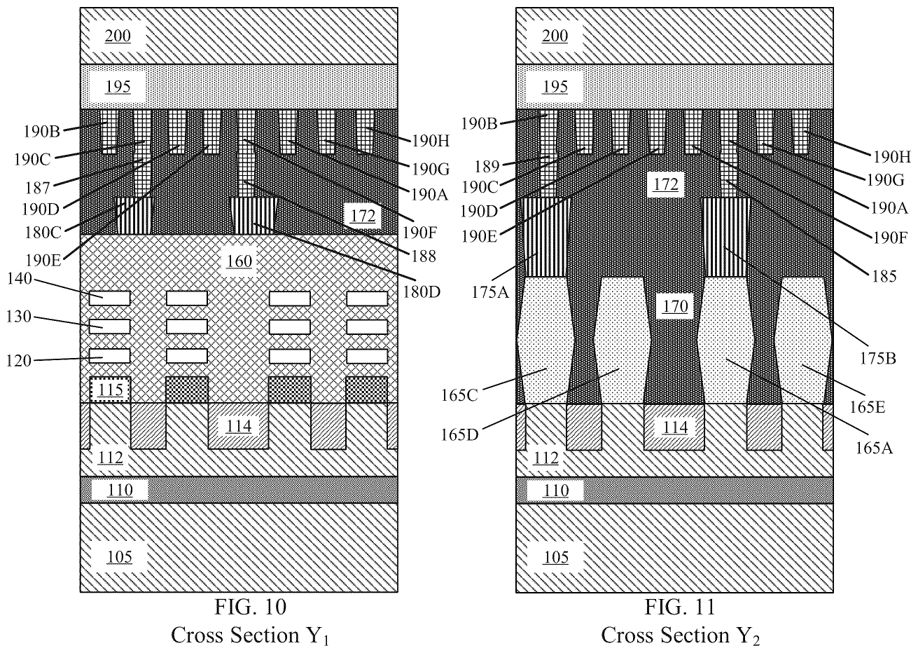

FIGS. 9-11 illustrate cross sections X, Y₁, and Y₂, respectively, of the plurality of nanodevices ND1, ND2, ND3, ND4 after the formation of a BEOL layer 195 and bonding to a carrier wafer 200, in accordance with the embodiment of the present invention. The BEOL layer 195 may contain multiple metal layers and vias in between. In FIG. 9, the BEOL layer 195 is formed directly atop the first frontside signal line 190A and the additional ILD 172. In FIGS. 10-11, the BEOL layer 195 is formed directly atop the plurality of frontside signal lines 190A, 190B, 190C, 190D, 190E, 190F, 190G, 190H and the additional ILD 172. In FIGS. 9-11, the carrier wafer 200 is formed directly atop the BEOL layer 195 by bonding processes (e.g., oxide-oxide bonding).

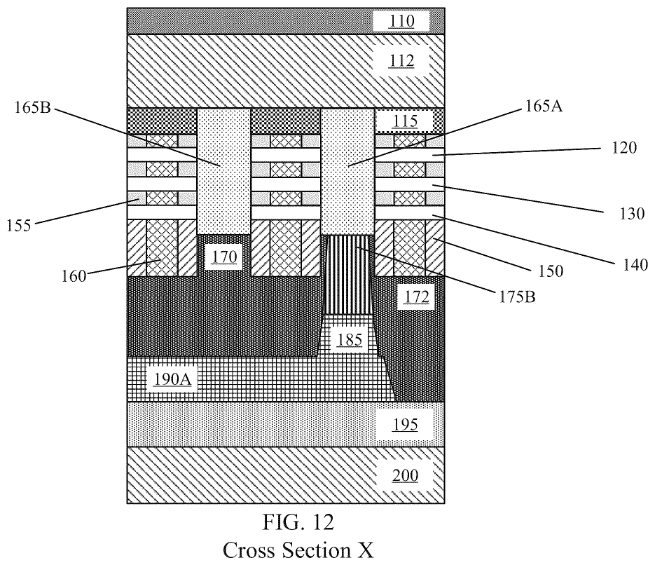

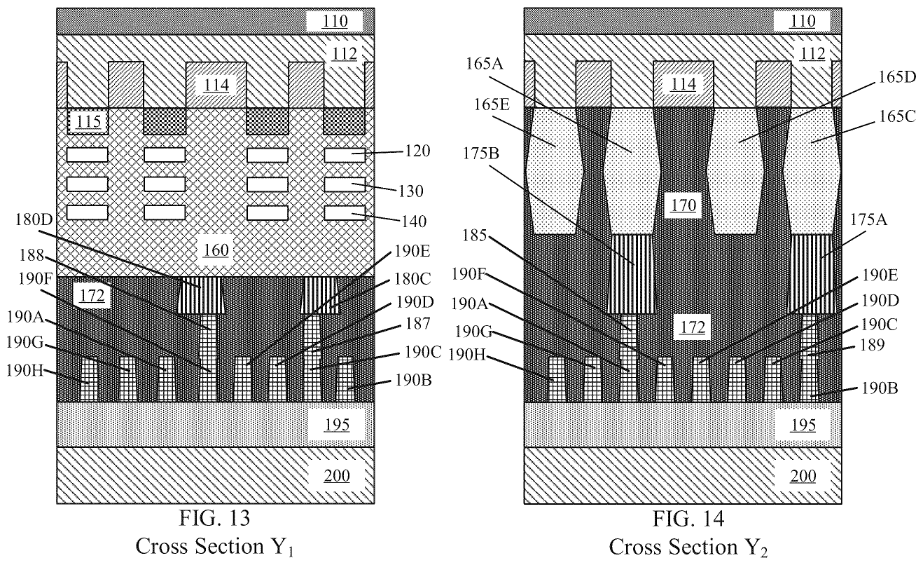

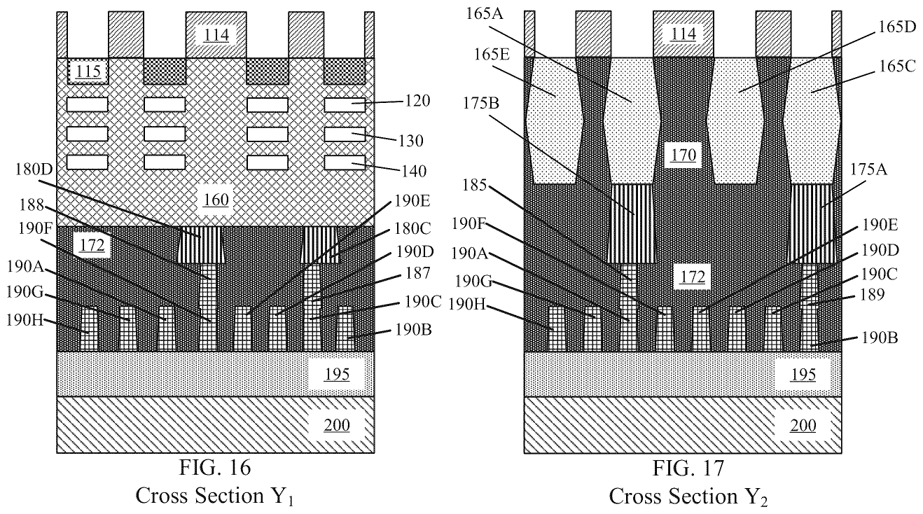

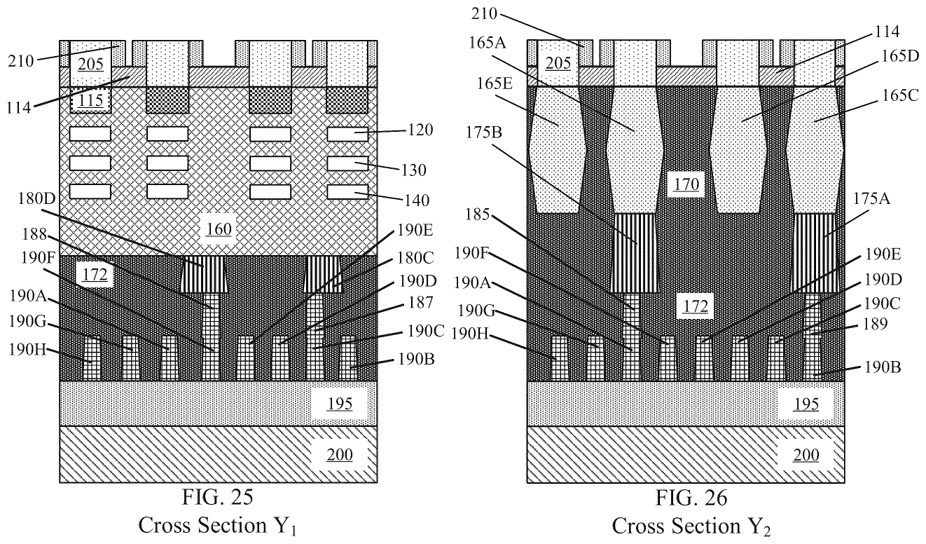

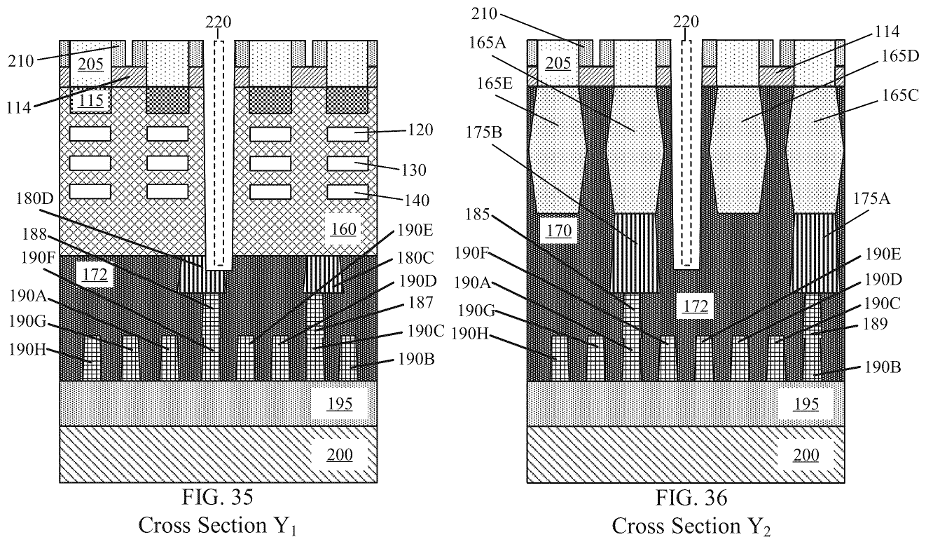

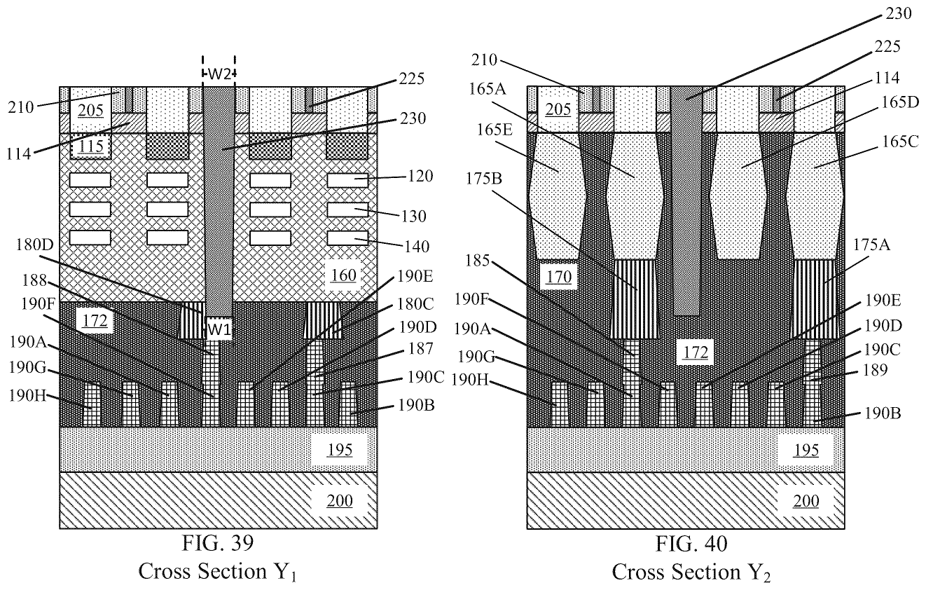

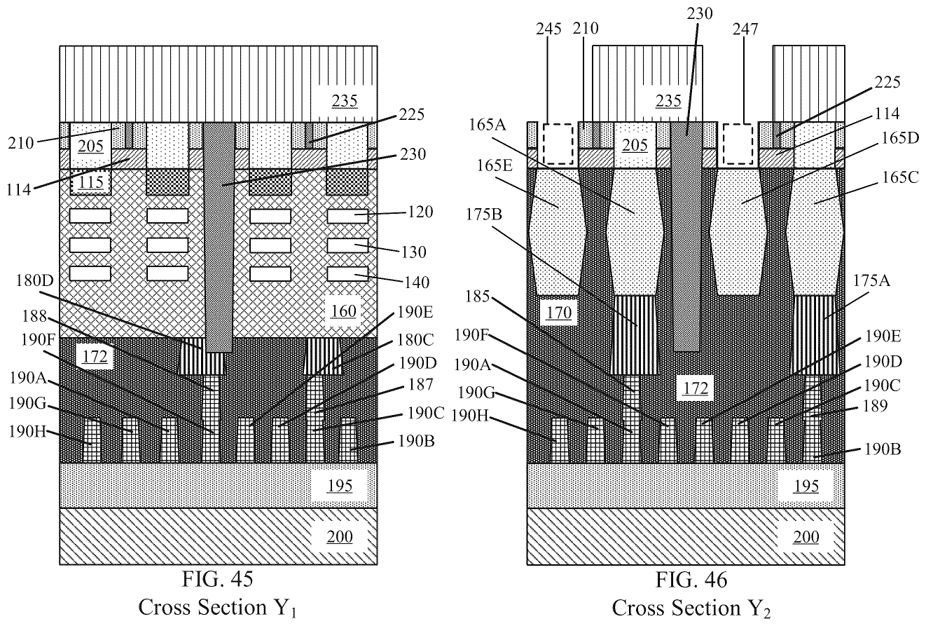

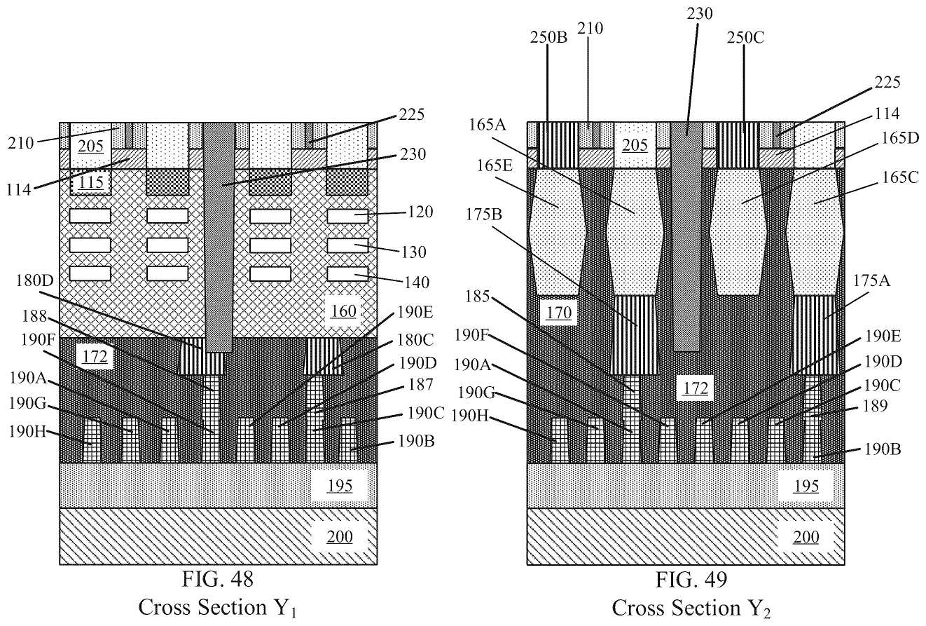

FIGS. 1-11 illustrate the processing of the frontside of the substrate 105, while FIGS. 12-52 illustrate the processing of the backside of the substrate 105. FIGS. 12-14 illustrate cross sections X, Y₁, and Y₂, respectively, of the plurality of nanodevices ND1, ND2, ND3, ND4 after the carrier wafer 200 is flipped and the substrate 105 is removed, in accordance with the embodiment of the present invention. The carrier wafer 200 is flipped and the carrier wafer 200 becomes a handler wafer. The substrate 105 is removed by, for example, a combination of processes such as wafer grinding, CMP, and/or selective dry/wet etch, stopping on the etch stop layer 110.

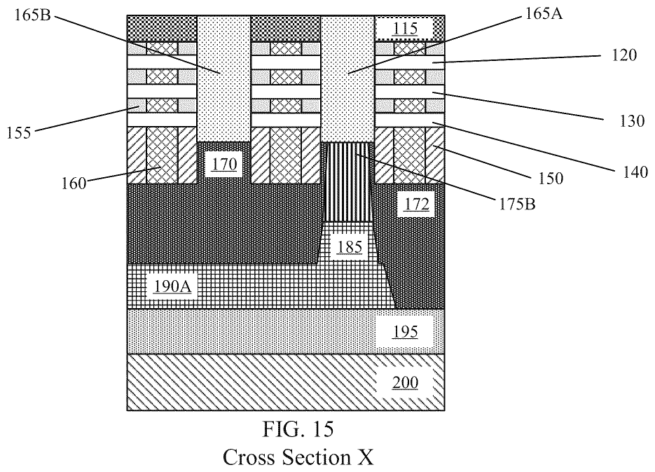

FIGS. 15-17 illustrate cross sections X, Y₁, and Y₂, respectively, of the plurality of nanodevices ND1, ND2, ND3, ND4 after the removal of the etch stop layer 110 and the underlying substrate layer 112, in accordance with the embodiment of the present invention. The etch stop layer 110 is removed to expose the underlying substrate layer 112. The underlying substrate layer 112 is removed by, for example, a selective wet or dry etch process.

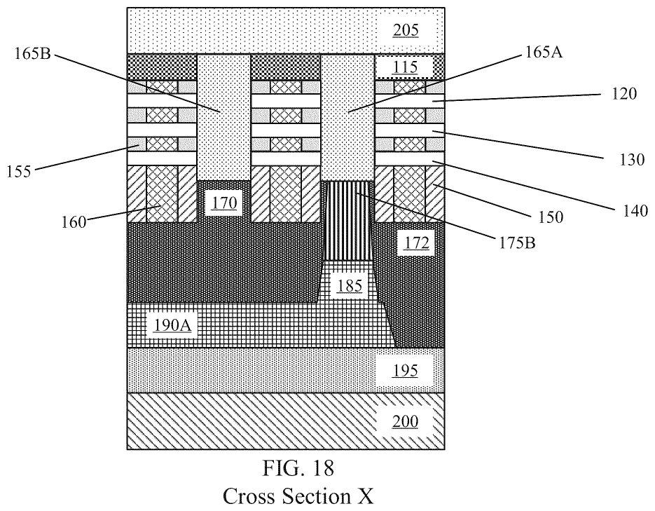

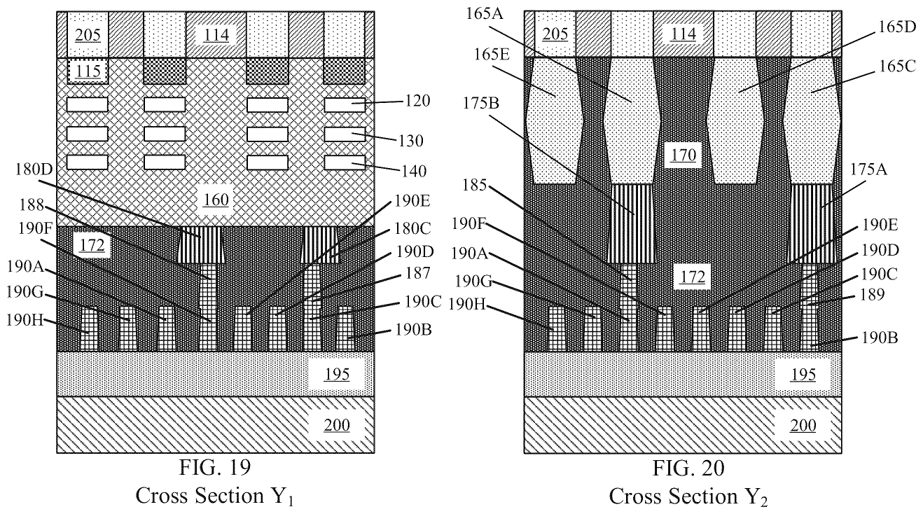

FIGS. 18-20 illustrate cross sections X, Y₁, and Y₂, respectively, of the plurality of nanodevices ND1, ND2, ND3, ND4 after backside ILD (BILD) layer 205 deposition and CMP, in accordance with the embodiment of the present invention. The BILD layer 205 may be comprised of, for example, SiC or SiOC. In FIG. 18, the BILD layer 205 is deposited directly atop the SASI layer 115, the first source/drain 165A, and the second source/drain 165B. In FIG. 19, the BILD layer 205 is deposited directly atop the SASI layer 115. In FIG. 20, the BILD layer 205 is deposited directly atop the first source/drain 165A, the third source/drain 165C, the fourth source/drain 165E, and the fifth source/drain 165E. In FIGS. 18-20, a portion of the BILD layer 205 is selectively removed by, for example, CMP.

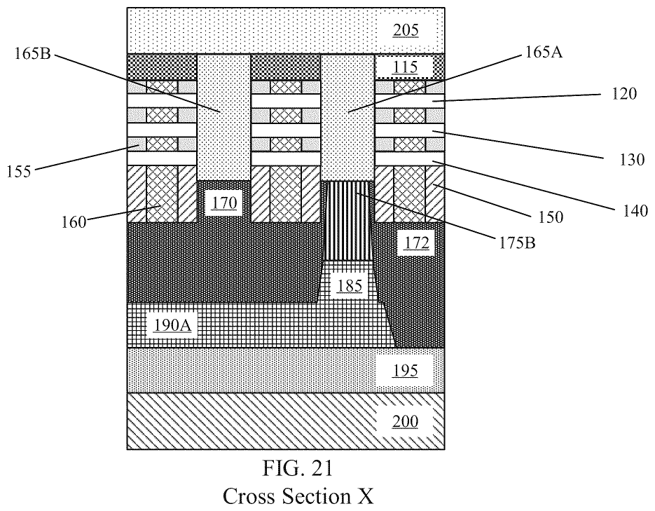

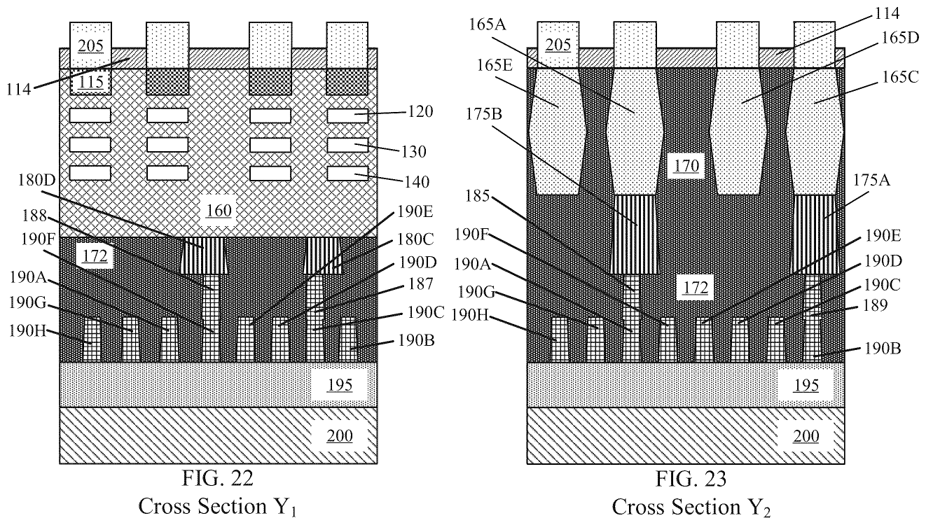

FIGS. 21-23 illustrate cross sections X, Y₁, and Y₂, respectively, of the plurality of nanodevices ND1, ND2, ND3, ND4 after the selective recessing of the STI region 114, in accordance with the embodiment of the present invention. A portion of the STI region 114 is removed by, for example, a selective wet or dry etch process. In FIGS. 22-23, a portion of sidewalls of the BILD layer 205 is exposed.

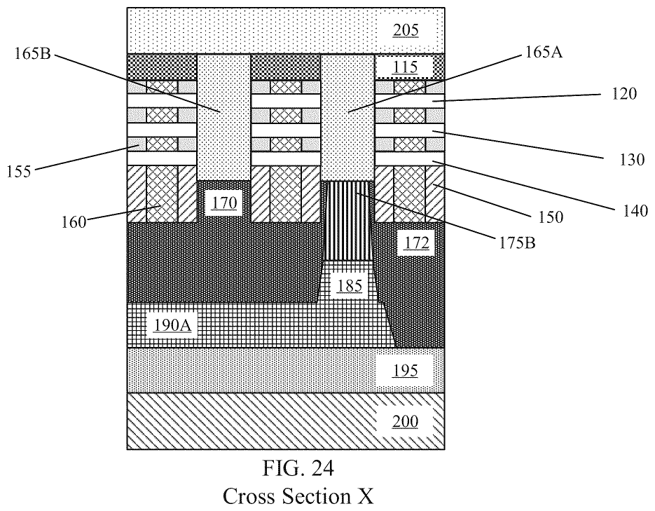

FIGS. 24-26 illustrate cross sections X, Y₁, and Y₂, respectively, of the plurality of nanodevices ND1, ND2, ND3, ND4 after the formation of a plurality of dielectric spacers 210, in accordance with the embodiment of the present invention. A spacer material (e.g., SiN or SiO₂) is deposited in a space created by the removal of the portion of the STI region 114 and etched back to form the plurality of dielectric spacers 210 located on the exposed portion of the sidewalls of the BILD layer 205.

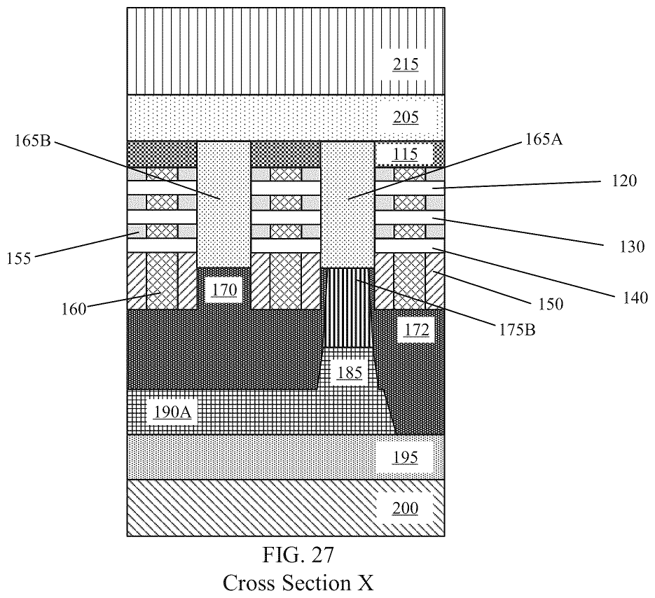

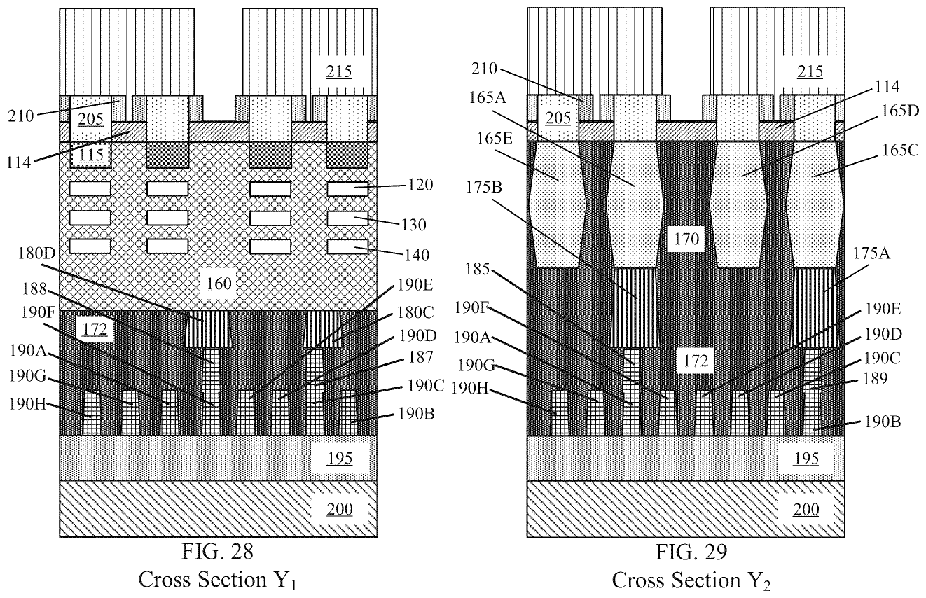

FIGS. 27-29 illustrate cross sections X, Y₁, and Y₂, respectively, of the plurality of nanodevices ND1, ND2, ND3, ND4 after the formation of a lithography mask layer 215, in accordance with the embodiment of the present invention. The lithography mask layer 215 may be, for example, an organic planarization layer (OPL). In FIG. 27, the lithography mask layer 215 is deposited directly atop the BILD layer 205. In FIGS. 28-29, the lithography mask layer 215 is deposited and then patterned directly atop the BILD layer 205, the plurality of dielectric spacers 210, and the STI region 114 to expose a portion of the STI region 114. In FIGS. 27-29, the lithography mask layer 215 is formed by depositing, for example, an OPL material in a spin-on coating process.

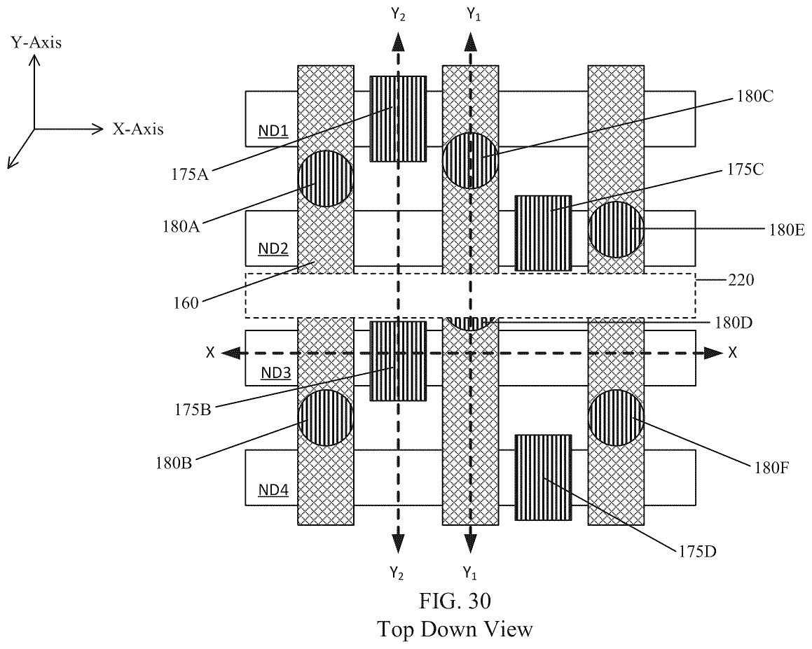

FIG. 30 illustrates a top-down view of the plurality of nanodevices ND1, ND2, ND3, ND4 after the formation of a first trench 220, in accordance with the embodiment of the present invention. FIG. 30 is meant to illustrate a cut (i.e., the first trench 220) in the gate 160 between the second nanodevice ND2 and the third nanodevice ND3.

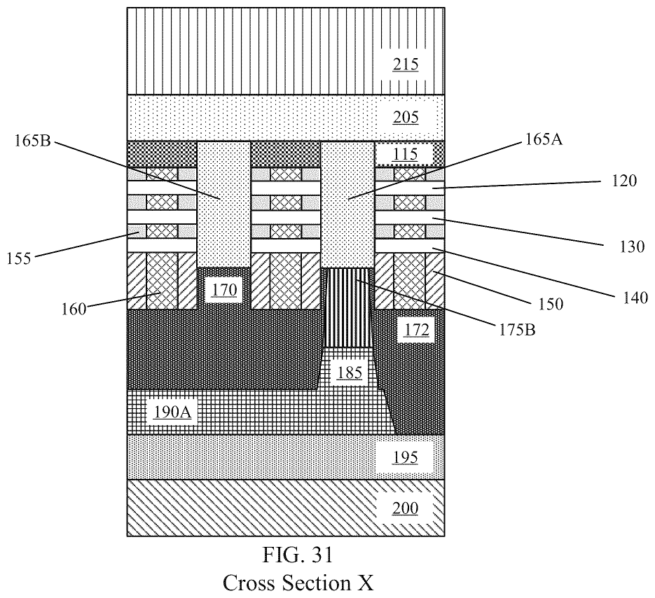

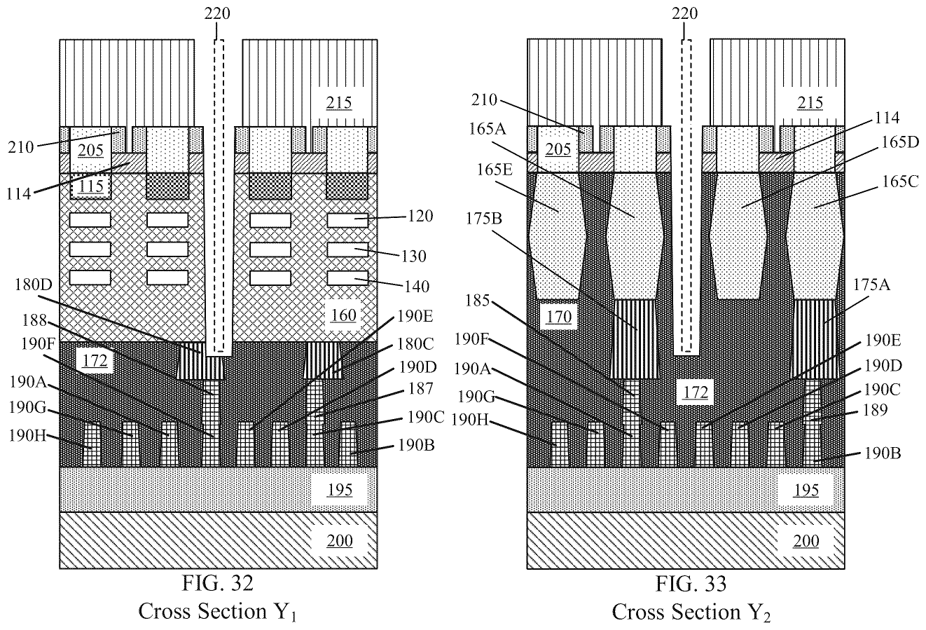

FIGS. 31-33 illustrate cross sections X, Y₁, and Y₂, respectively, of the plurality of nanodevices ND1, ND2, ND3, ND4 after the formation of the first trench 220, in accordance with the embodiment of the present invention. In FIG. 32, the exposed portion of the STI region 114, the gate 160, the additional ILD 172, and the fourth gate contact 180D are etched by, for example, RIE to form the first trench 220. A bottom surface of the first trench 220 exposes a portion of a top surface of the additional ILD 172 and the fourth gate contact 180D. The fourth gate contact 180D includes a recessed portion. The fourth gate contact 180D has substantially an L-shaped profile through a cross section of the gate region 102 (FIG. 1). In FIG. 33, the exposed portion of the STI region 114, the ILD 170, and the additional ILD 172 are etched by, for example, RIE to form the first trench 220. A bottom surface of the first trench 220 exposes a portion of a top surface of the additional ILD 172.

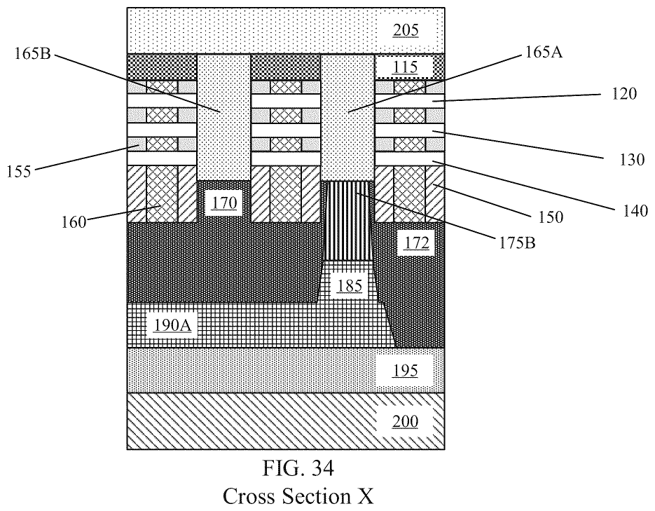

FIGS. 34-36 illustrate cross sections X, Y₁, and Y₂, respectively, of the plurality of nanodevices ND1, ND2, ND3, ND4 after the removal of the lithography mask layer 215, in accordance with the embodiment of the present invention. The lithography mask layer 215 is removed to expose a top surface of the BILD layer 205 and the plurality of dielectric spacers 210.

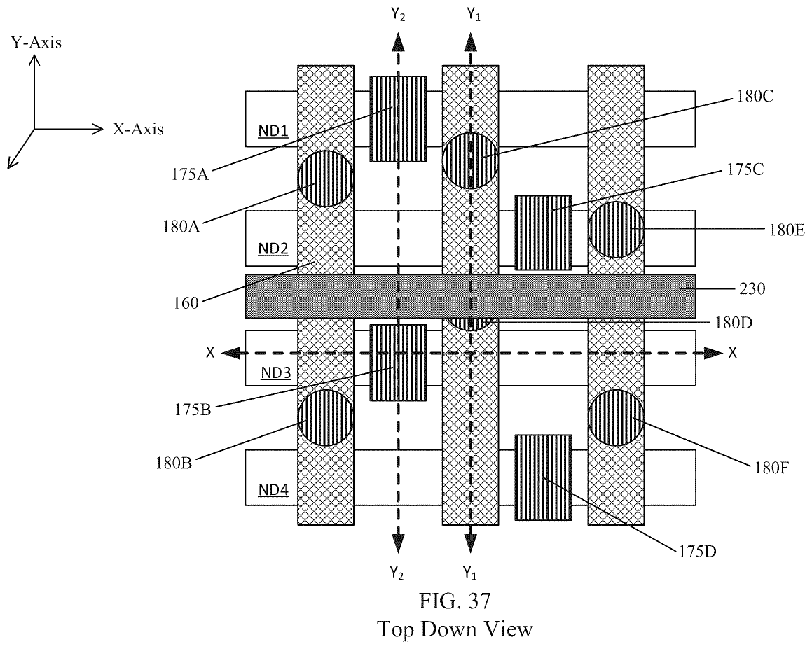

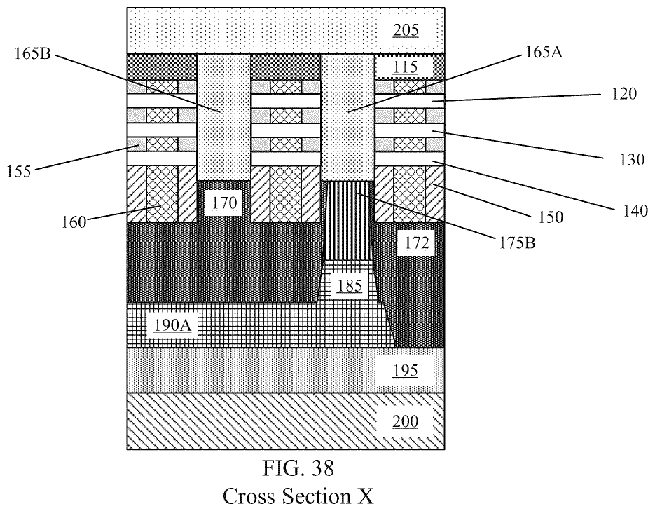

FIG. 37 illustrates a top-down view of the plurality of nanodevices ND1, ND2, ND3, ND4 after the formation of a plurality of dielectric fills 225 (FIGS. 38-40), a backside gate cut dielectric pillar 230, and CMP, in accordance with the embodiment of the present invention. FIG. 37 is meant to illustrate the cut in the gate 160 is filled to form the backside gate cut dielectric pillar 230.

FIGS. 38-40 illustrate cross sections X, Y₁, and Y₂, respectively, of the plurality of nanodevices ND1, ND2, ND3, ND4 after the formation of the plurality of dielectric fills 225, the backside gate cut dielectric pillar 230, and CMP, in accordance with the embodiment of the present invention. A dielectric fill material is deposited in the first trench 220 to form the backside gate cut dielectric pillar 230. The dielectric fill material is also deposited directly atop the STI region 114 in a space created by the removal of the lithography mask layer 215 to form the plurality of dielectric fills 225. Then, a portion of the plurality of dielectric fills 225 and the backside gate cut dielectric pillar 230 are selectively removed by, for example, CMP to expose a top surface of the BILD layer 205 and the plurality of dielectric spacers 210. The plurality of dielectric fills 225 and the backside gate cut dielectric pillar 230 may be comprised of, for example, SiO₂ or SiN. According to the embodiment of the present invention, the plurality of dielectric fills 225 and the backside gate cut dielectric pillar 230 may be comprised of a same dielectric material, and the plurality of dielectric spacers 210 may be comprised of a different dielectric material than the plurality of dielectric fills 225 and the backside gate cut dielectric pillar 230.

The backside gate cut dielectric pillar 230 extends downwards through the recessed portion of the fourth gate contact 180D to be in direct contact with the fourth gate contact 180D. As described above with respect to the description of FIGS. 31-33, the fourth gate contact 180D has substantially the L-shaped profile through the cross section of the gate region 102 (FIG. 1). The backside gate cut dielectric pillar 230 is in direct contact with a horizontal section of the L-shaped profile of the fourth gate contact 180D. The backside gate cut dielectric pillar 230 includes a frontside surface and a backside surface. The frontside surface that is in direct contact with the fourth gate contact 180D extends a first width W1 along a y-axis. The backside surface extends a second width W2 along the y-axis. The second width W2 is greater than the first width W1. The fourth gate contact 180D is in direct contact with a sidewall of the backside gate cut dielectric pillar 230. The backside gate cut dielectric pillar 230 progressively narrows from the backside surface to the frontside surface. The backside gate cut dielectric pillar 230 extends downwards between the first source/drain 165A and the fourth source/drain 165D (i.e., the plurality of source/drains in the claims).

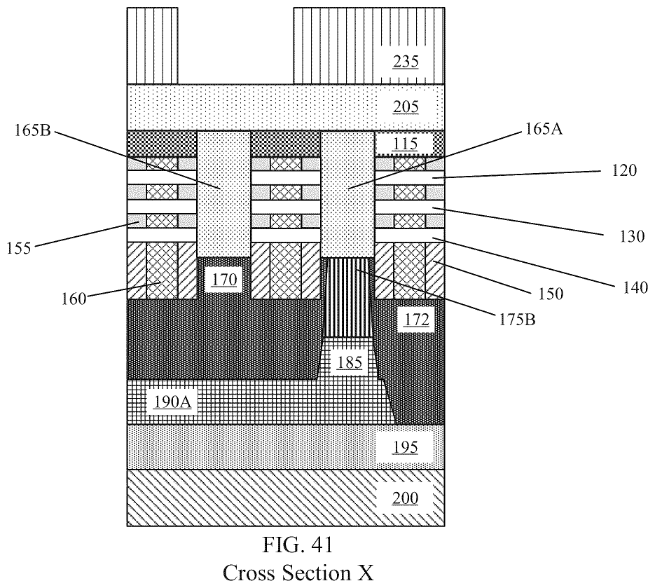

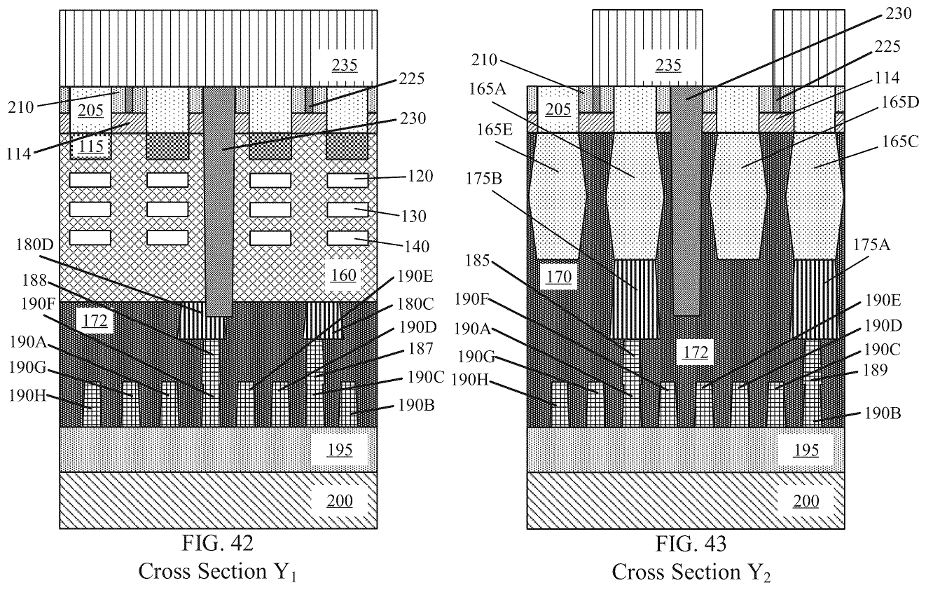

FIGS. 41-43 illustrate cross sections X, Y₁, and Y₂, respectively, of the plurality of nanodevices ND1, ND2, ND3, ND4 after the formation of a second lithography mask layer 235, in accordance with the embodiment of the present invention. The second lithography mask layer 235 may be, for example, an organic planarization layer (OPL). In FIG. 41, the second lithography mask layer 235 is deposited and then patterned directly atop the BILD layer 205 to expose a portion of the BILD layer 205. In FIG. 42, the second lithography mask layer 235 is deposited directly atop the BILD layer 205, the plurality of dielectric spacers 210, the plurality of dielectric fills 225, and the backside gate cut dielectric pillar 230. In FIG. 43, the second lithography mask layer 235 is deposited and then patterned directly atop the BILD layer 205, the plurality of dielectric spacers 210, the plurality of dielectric fills 225, and the backside gate cut dielectric pillar 230 to expose a portion of the plurality of dielectric spacers 210 and the BILD layer 205. In FIGS. 41-43, the second lithography mask layer 235 is formed by depositing, for example, an OPL material in a spin-on coating process.

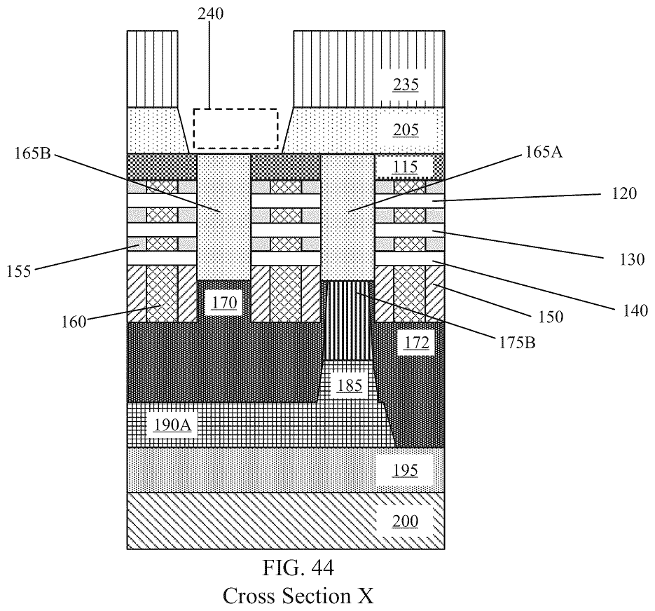

FIGS. 44-46 illustrate cross sections X, Y₁, and Y₂, respectively, of the plurality of nanodevices ND1, ND2, ND3, ND4 after the formation of a second trench 240, a third trench 245, and a fourth trench 247, in accordance with the embodiment of the present invention. In FIG. 44, the exposed portion of the BILD layer 205 is etched by, for example, RIE to form the second trench 240. A bottom surface of the second trench 240 exposes a portion of a top surface of the SASI layer 115 and the second source/drain 165B. In FIG. 46, the exposed portion of the BILD layer 205 is etched by, for example, RIE to form the third trench 245 and the fourth trench 247. A bottom surface of the third trench 245 exposes a top surface of the fifth source/drain 165E. A bottom surface of the fourth trench 247 exposes a top surface of the fourth source/drain 165D.

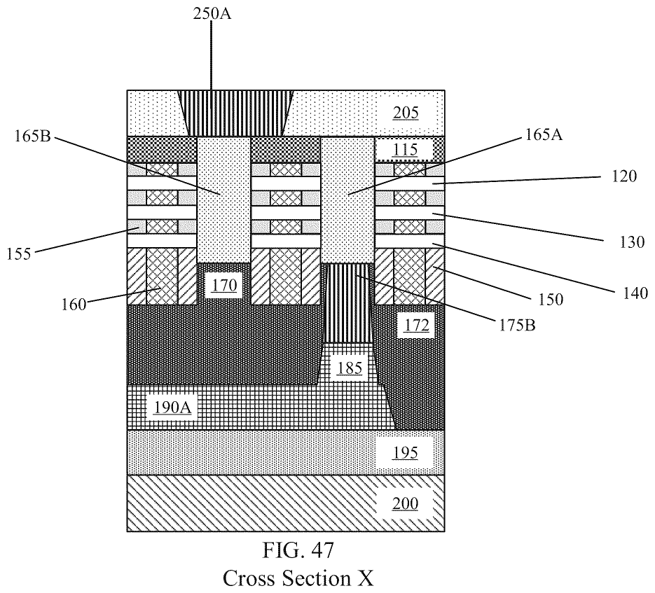

FIGS. 47-49 illustrate cross sections X, Y₁, and Y₂, respectively, of the plurality of nanodevices ND1, ND2, ND3, ND4 after the formation of a plurality of backside contacts 250A, 250B, 250C, in accordance with the embodiment of the present invention. The second trench 240, the third trench 245, and the fourth trench 247 are filled with a conductive metal (e.g., including a silicide liner, such as Ni, Ti, NiPt, an adhesion metal liner, such as TiN and conductive metal fill, such as W, Co, or Ru) to form the plurality of backside contacts 250A, 250B, 250C. In FIG. 47, the first backside contact 250A is located directly atop the second source/drain 165B and the SASI layer 115. In FIG. 49, the second backside contact 250B is located directly atop the fifth source/drain 165E. The third backside contact 250C is located directly atop the fourth source/drain 165D. In FIGS. 47 and 49, at least one backside contact (i.e., the first backside contact 250A, the second backside contact 250B, and/or the third backside contact 250C) is in direct contact with a backside of a respective source/drain (i.e., the second source/drain 165B, the fourth source/drain 165D, and/or the fifth source/drain 165E) of the plurality of source/drains 165A, 165B, 165C, 165D, 165E.

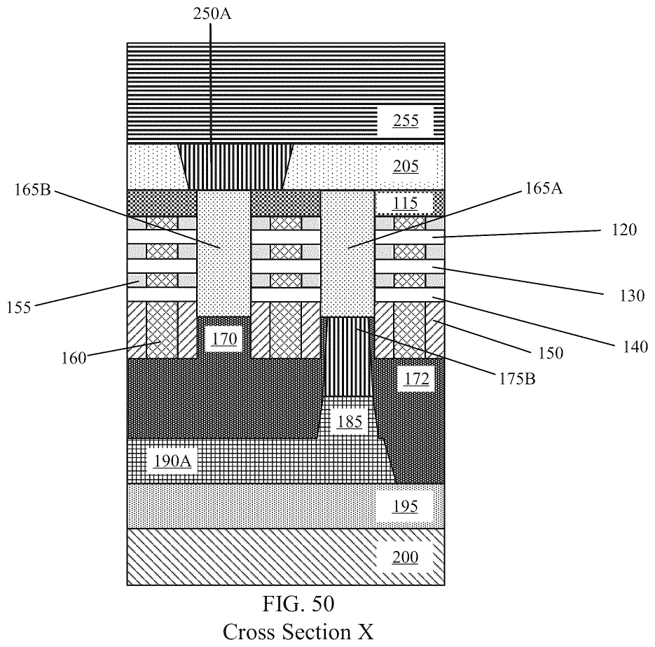

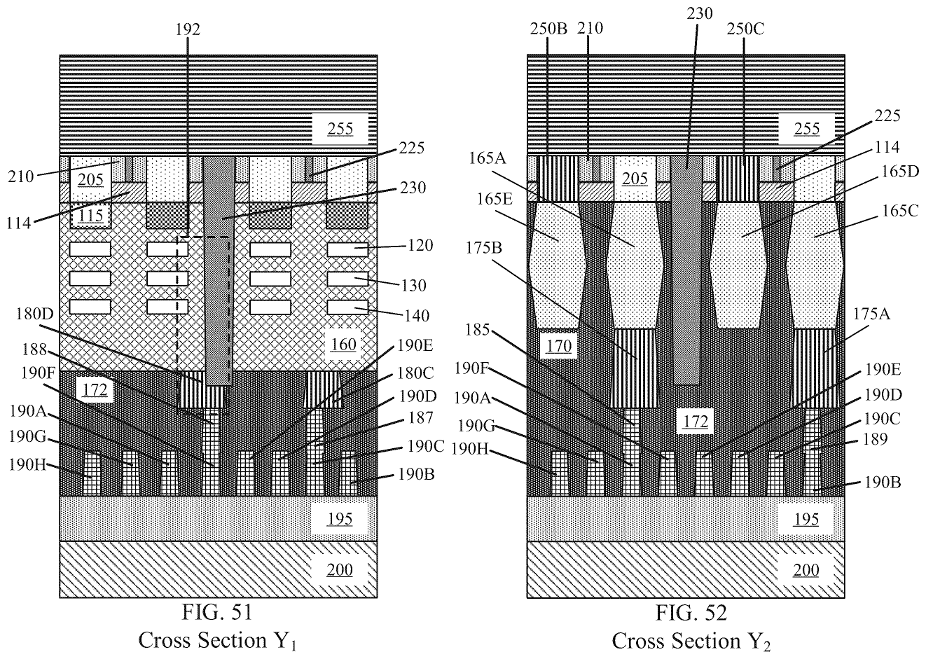

FIGS. 50-52 illustrate cross sections X, Y₁, and Y₂, respectively, of the plurality of nanodevices ND1, ND2, ND3, ND4 after the formation of a BSPDN 255, in accordance with the embodiment of the present invention. In FIG. 50, the BSPDN 255 is formed directly atop the BILD layer 205 and the first backside contact 250A. In FIG. 51, the BSPDN 255 is formed directly atop the BILD layer 205, the plurality of dielectric spacers 210, the plurality of dielectric fills 225, and the backside gate cut dielectric pillar 230. In FIG. 52, the BSPDN 255 is formed directly atop the BILD layer 205, the plurality of dielectric spacers 210, the plurality of dielectric fills 225, the backside gate cut dielectric pillar 230, the second backside contact 250B, and the third backside contact 250C.

In FIGS. 51-52, the BSPDN 255 is in direct contact with the backside surface of the backside gate cut dielectric pillar 230. The plurality of dielectric spacers 210 are in direct contact with a frontside of the BSPDN 255. Two dielectric spacers of the plurality of dielectric spacers 210 are in direct contact with sidewalls of the backside gate cut dielectric pillar 230. The plurality of dielectric fills 225 are located between a different two respective dielectric spacers of the plurality of dielectric spacers 210. The BILD layer 205 is located between another different two dielectric spacers of the plurality of dielectric spacers 210. The BILD layer 205 and the plurality of dielectric spacers 210 may be comprised of a different dielectric material. In FIGS. 50 and 52, the respective source/drain (i.e., the second source/drain 165B, the fourth source/drain 165D, and/or the fifth source/drain 165E) is connected to the BSPDN 255 by the at least one backside contact (i.e., the first backside contact 250A, the second backside contact 250B, and/or the third backside contact 250C). As described above with respect to FIG. 7, in FIG. 51 dashed box 192 illustrates the fourth gate contact 180D partially overlapping the third nanodevice ND3. Dashed box 192 also illustrates the sixth frontside signal line 190F located at the cell boundary between two nanodevices ND2, ND3 of the plurality of nanodevices ND1, ND2, ND3, ND4.

The fourth gate contact 180D is located at the edge of the cell boundary between the second nanodevice ND2 and the third nanodevice ND3. The backside gate cut dielectric pillar 230 extends downwards through the recessed portion of the fourth gate contact 180D to be in direct contact with the fourth gate contact 180D. The backside gate cut dielectric pillar 230 is comprised of a frontside surface and a backside surface. The frontside surface extends a first width W1 parallel to the x-axis. The backside surface extends a second width W2 parallel to the x-axis. The second width W2 is greater than the first width W1.

It may be appreciated that FIGS. 1-52 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a plurality of nanodevices including a plurality of transistors, wherein the plurality of nanodevices are located adjacent to and parallel to each other along an x-axis;
a gate contact located at an edge of a cell boundary between two nanodevices of the plurality of nanodevices, wherein the gate contact includes a recessed portion; and
a backside gate cut dielectric pillar extending downwards through the recessed portion to be in direct contact with the gate contact.

2. The semiconductor device of claim 1, wherein the gate contact has substantially an L-shaped profile through a cross section of a gate region.

3. The semiconductor device of claim 2, wherein the backside gate cut dielectric pillar is in direct contact with a horizontal section of the L-shaped profile of the gate contact.

4. The semiconductor device of claim 3, wherein a frontside surface of the backside gate cut dielectric pillar that is in direct contact with the gate contact has a first width along a y-axis, wherein a backside surface of the backside gate cut dielectric pillar extends a second width along the y-axis, and wherein the second width is greater than the first width.

5. The semiconductor device of claim 4, wherein the gate contact is in direct contact with a sidewall of the backside gate cut dielectric pillar.

6. The semiconductor device of claim 5, wherein the plurality of nanodevices include at least a first nanodevice, a second nanodevice, a third nanodevice, and a fourth nanodevice, and wherein the gate contact is located between the second nanodevice and the third nanodevice.

7. The semiconductor device of claim 6, wherein the gate contact partially overlaps the third nanodevice.

8. A semiconductor device comprising:
a plurality of nanodevices including a plurality of transistors, wherein the plurality of nanodevices are located adjacent to and parallel to each other along an x-axis;
a gate contact located at an edge of a cell boundary between two nanodevices of the plurality of nanodevices, wherein the gate contact includes a recessed portion;
a backside gate cut dielectric pillar extending downwards through the recessed portion to be in direct contact with the gate contact; and
a frontside signal line located at the cell boundary between the two nanodevices.

9. The semiconductor device of claim 8, wherein the frontside signal line includes a via connected to a frontside of the gate contact.

10. The semiconductor device of claim 9, wherein a frontside surface of the backside gate cut dielectric pillar that is in direct contact with the gate contact has a first width along a y-axis, wherein a backside surface of the backside gate cut dielectric pillar extends a second width along the y-axis, and wherein the second width is greater than the first width.

11. The semiconductor device of claim 10, wherein the backside gate cut dielectric pillar progressively narrows from the backside surface to the frontside surface.

12. The semiconductor device of claim 11, further comprising:
a backside power distribution network (BSPDN) in direct contact with the backside surface of the backside gate cut dielectric pillar.

13. The semiconductor device of claim 12, further comprising:
a plurality of dielectric spacers in direct contact with a frontside of the BSPDN, wherein two dielectric spacers of the plurality of dielectric spacers are in direct contact with sidewalls of the backside gate cut dielectric pillar.

14. The semiconductor device of claim 13, further comprising:
a plurality of dielectric fills located between a different two respective dielectric spacers of the plurality of dielectric spacers, wherein the backside gate cut dielectric pillar and the plurality of dielectric fills are comprised of a same dielectric material, and wherein the plurality of dielectric spacers are comprised of a different dielectric material than the plurality of dielectric fills and the backside gate cut dielectric pillar.

15. A semiconductor device comprising:
a plurality of nanodevices including a plurality of transistors, wherein the plurality of nanodevices include a plurality of source/drains, and wherein the plurality of nanodevices are located adjacent to and parallel to each other along an x-axis;
a gate contact located at an edge of a cell boundary between two nanodevices of the plurality of nanodevices, wherein the gate contact includes a recessed portion;
a backside gate cut dielectric pillar extending downwards through the recessed portion to be in direct contact with the gate contact; and
a frontside signal line located at the cell boundary between the two nanodevices.

16. The semiconductor device of claim 15, wherein a frontside surface of the backside gate cut dielectric pillar that is in direct contact with the gate contact has a first width along a y-axis, wherein a backside surface of the backside gate cut dielectric pillar extends a second width along the y-axis, and wherein the second width is greater than the first width.

17. The semiconductor device of claim 16, wherein the backside gate cut dielectric pillar extends downwards between the plurality of source/drains.

18. The semiconductor device of claim 17, further comprising:
a backside power distribution network (BSPDN) in direct contact with the backside surface of the backside gate cut dielectric pillar; and
a plurality of dielectric spacers in direct contact with a frontside of the BSPDN, wherein two dielectric spacers of the plurality of dielectric spacers are in direct contact with sidewalls of the backside gate cut dielectric pillar.

19. The semiconductor device of claim 18, further comprising:
a backside interlayer dielectric (BILD) layer located between a different two dielectric spacers of the plurality of dielectric spacers, wherein the BILD layer and the plurality of dielectric spacers are comprised of a different dielectric material.

20. The semiconductor device of claim 19, further comprising:
a backside contact in direct contact with a backside of a source/drain of the plurality of source/drains, wherein the source/drain is connected to the BSPDN by the backside contact.
